(19) United States
(12) Patent Application Publication
(10) Pub. No.: US 2026/0155711 A1
(43) Pub. Date: Jun. 4, 2026

(54) MOTOR CONTROL DEVICE

(71) Applicant: MITSUBA Corporation, Gunma (JP)

(72) Inventor: NOBUHIRO SHIMIZU, Gunma (JP)

(73) Assignee: MITSUBA Corporation, Gunma (JP)

(21) Appl. No.: 18/866,554

(22) PCT Filed: May 14, 2024
(86) PCT No.: PCT/JP2024/017736

§ 371 Date: Nov. 17, 2024

(30) Foreign Application Priority Data
Sep. 29, 2023 (JP) 2023-169775
Apr. 18, 2024 (JP) 2024-067796

(51) Int. Cl. H02K 11/00; H02K 11/30

(52) U.S. Cl. CPC H02K 11/0094; H02K 11/30; H02K 2211/03

(57) ABSTRACT

The present invention provides a motor control device that can easily achieve miniaturization while securing the insulation distance between a busbar and a substrate. The motor control device according to the present invention includes a printed circuit board 20 on which a switching element 22 is surface-mounted; busbars 31 and 32 that are surface-mounted on the printed circuit board 20 and are connected to the switching element 22; and an electrolytic capacitor 60 that is electrically connected to the switching element 22 via the busbars 31 and 32. The busbars 31 and 32 have main bodies 41 and 51 connected to the printed circuit board 20, and busbar terminals 42 and 52 that are linked to the main bodies 41 and 51 and are connected to the electrolytic capacitor 60. The busbar terminals 42 and 52 have rising portions that rise from a surface 20b of the printed circuit board 20, and capacitor connection portions 47 and 57 that are bent and extend from the tips of the rising portions toward the electrolytic capacitor 60 and are connected to the electrolytic capacitor 60.

### TECHNICAL FIELD

The present invention relates to a motor control device.

### RELATED ART

Conventionally, there is known a motor control device that converts DC power supplied from a battery into AC power and drives an AC motor (hereinafter also referred to as motor) with the converted AC power. The motor control device includes a substrate (switching module) on which a switching element is surface-mounted. In addition to the switching element, an electrolytic capacitor (hereinafter also referred to as capacitor) for smoothing the current flowing through the motor is surface-mounted (SMT: Surface Mount Technology) on the substrate. Here, in the case where the inductance of the current path (conduction distance) is large, the ripple current flowing through the capacitor may increase, potentially causing thermal damage to the capacitor.

As countermeasures, there are methods such as selecting capacitors capable of absorbing the ripple current or increasing the number of capacitors. However, from the viewpoints of miniaturization and cost reduction of the motor control device, it is preferable to implement countermeasures that reduce inductance. To reduce inductance, it is effective to shorten the current path or to arrange the input and output in parallel with a large opposing area therebetween.

A known motor control device that arranges the input and output in parallel with a large opposing area, for example, has the switching element, which is a heating element, and the capacitor connected by a busbar. The busbar is integrally formed with a first terminal connected to the switching element, a second terminal connected to the capacitor, and a linking portion that links the first terminal and the second terminal. The first terminal is bent toward the capacitor.

There are positive and negative busbars, and the positive linking portion and the negative linking portion are arranged to be opposed to each other. The busbar is formed with a bend in an L-shape with the end portion of the first terminal on the capacitor side rising from the substrate. The second terminal is formed at the tip of this bent busbar. This secures the insulation distance between the substrate and the connection point (second terminal) of the busbar with the capacitor (see, for example, Patent Document 1).

### CITATION LIST

### Patent Document

Patent Document 1: Japanese Patent Application Laid-Open No. 2003-319665

### SUMMARY OF INVENTION

### Technical Problem

However, the busbar in the aforementioned motor control device is simply bent in an L-shape to rise from the substrate, which results in low flexibility in layout for the capacitor. Therefore, there is a problem that the motor control device tends to be larger in size.

Thus, the present invention provides a motor control device that can easily achieve miniaturization while securing the insulation distance between the busbar and the substrate.

### Solution to Problem

To solve the above problem, according to the first aspect of the present invention, a motor control device includes: a substrate on which a heating element is surface-mounted; a busbar that is surface-mounted on the substrate and is connected to the heating element; and a capacitor that is arranged alongside the substrate along an extending direction of the substrate and is electrically connected to the heating element via the busbar, in which the busbar has: a main body that is connected to the substrate; and a busbar terminal that is linked to the main body and is connected to the capacitor, and the busbar terminal has: a rising portion that rises from a surface of the substrate; and a connection portion that is bent and extends from an end portion of the rising portion on a side opposite to the substrate toward the capacitor, and is connected to the capacitor.

By configuring the busbar terminal with the rising portion and the connection portion in this manner, the flexibility in layout of the capacitor in the normal direction of the substrate can be improved. Therefore, it is easy to achieve miniaturization of the motor control device while securing the insulation distance between the substrate and the connection portion of the busbar.

According to the second aspect of the present invention, the motor control device of the first aspect includes a plurality of the capacitors, in which each of the capacitors has a lead terminal connected to the connection portion respectively, each of the lead terminals is arranged to align in one direction, the busbar has a plurality of the busbar terminals connected to the plurality of the capacitors, and each of the connection portions is arranged to align in the same direction as an alignment direction of the lead terminals.

By configuring in this manner, while achieving miniaturization of the motor control device, the connection operation between the lead terminal and the busbar terminal can be facilitated, thereby improving the productivity of the motor control device.

According to the third aspect of the present invention, in the motor control device of the first aspect or second aspect, the busbar includes a first busbar and a second busbar connected to each one of the capacitors respectively, the main body includes a first main body provided on the first busbar and a second main body provided on the second busbar, and the first main body and the second main body are arranged to be opposed to each other in an alignment direction of the heating element and the capacitor, between the heating element and the capacitor.

By arranging the first main body and the second main body to be opposed to each other in the alignment direction of the heating element and the capacitor, it is possible to shorten the current path between each busbar terminal and the heating element while achieving miniaturization of the motor control device. Therefore, inductance can be reduced, and the insulation distance between the heating element and the capacitor can also be secured via the busbar.

According to the fourth aspect of the present invention, in the motor control device of any one of the first aspect to third aspect, the main body includes a tongue portion extending from an end portion of the main body on a side opposite to the substrate.

By configuring in this manner, for example, when assembling the motor control device, the busbar can be easily transported to a desired position by grasping the tongue portion. Therefore, while achieving miniaturization of the motor control device, the assembly workability of the motor control device can be improved.

According to the fifth aspect of the present invention, in the motor control device of the fourth aspect, the tongue portion extends in a direction parallel to the substrate.

By configuring in this manner, for example, when transporting the busbar, it is possible to hold and lift the tongue portion by suction while maintaining the posture of the main body aligned with the normal direction of the substrate. Therefore, the assembly workability of the motor control device can be further improved.

According to the sixth aspect of the present invention, in the motor control device of any one of the first aspect to fifth aspect, the main body includes a leg portion protruding from a side surface of the main body and being in contact with the substrate.

Here, in the case where the main body is arranged along the normal direction of the substrate, the posture of the busbar becomes unstable. In such a state, the leg portion protrudes from the side surface of the main body and is in contact with the substrate. Therefore, the leg portion can function to prevent the busbar from falling. Thus, while achieving miniaturization of the motor control device, the reliability of the motor control device can be improved.

According to the seventh aspect of the present invention, in the motor control device of the sixth aspect, the leg portion is connected to the substrate.

By configuring in this manner, the posture of the busbar relative to the substrate can be reliably maintained without increasing the size of the busbar. Therefore, the reliability of the motor control device can be further improved.

### Effects of Invention

According to the present invention, a motor control device is provided that can easily achieve miniaturization while securing the insulation distance between a busbar and a substrate.

### BRIEF DESCRIPTION OF DRAWINGS

FIG. 1 is a perspective view showing the motor control device in an embodiment of the present invention.

FIG. 2 is an arrow view of II in FIG. 1.

FIG. 3 is a perspective view of the motor control device in an embodiment of the present invention with the case removed.

FIG. 4 is an exploded perspective view of the motor control device shown in FIG. 3.

FIG. 5 is a view showing the connection state between the busbar and the capacitor in an embodiment of the present invention.

FIG. 6 is a plan view showing the electrolytic capacitor and the area around from the arrow view of VI in FIG. 3.

FIG. 7 is a perspective view of the motor control device in a modified example of an embodiment of the present invention with the case removed.

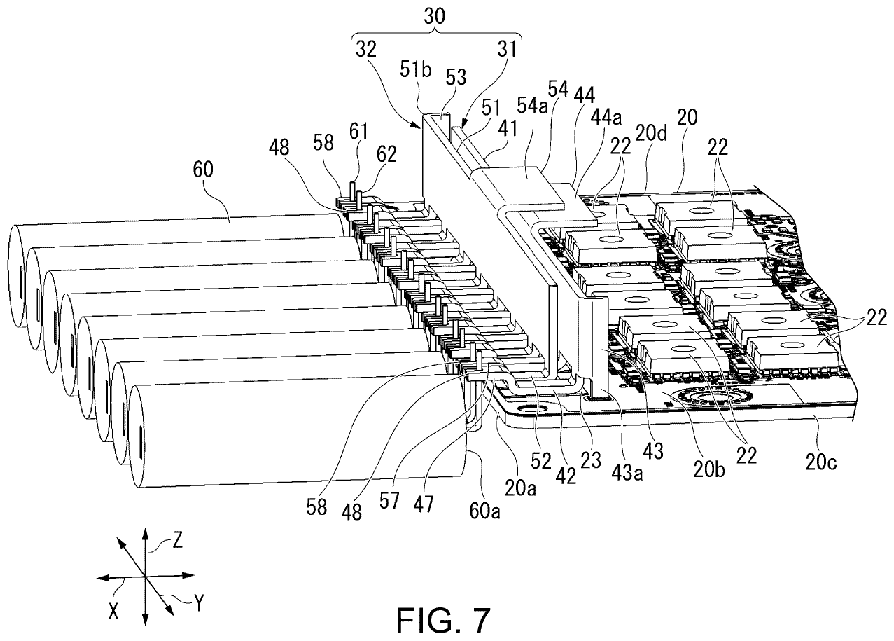

### DESCRIPTION OF EMBODIMENTS

Next, embodiments of the present invention will be described based on the figures.

### Motor Control Device

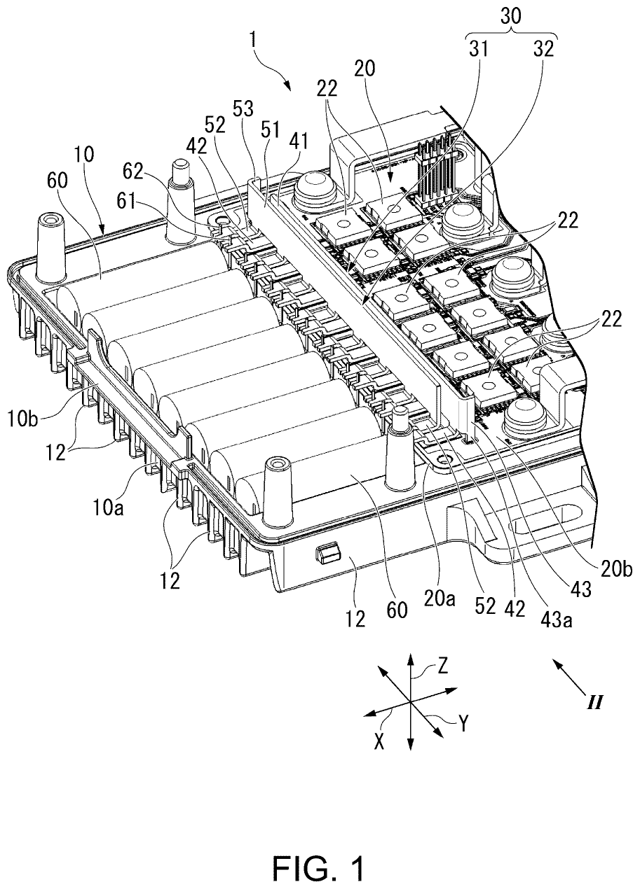

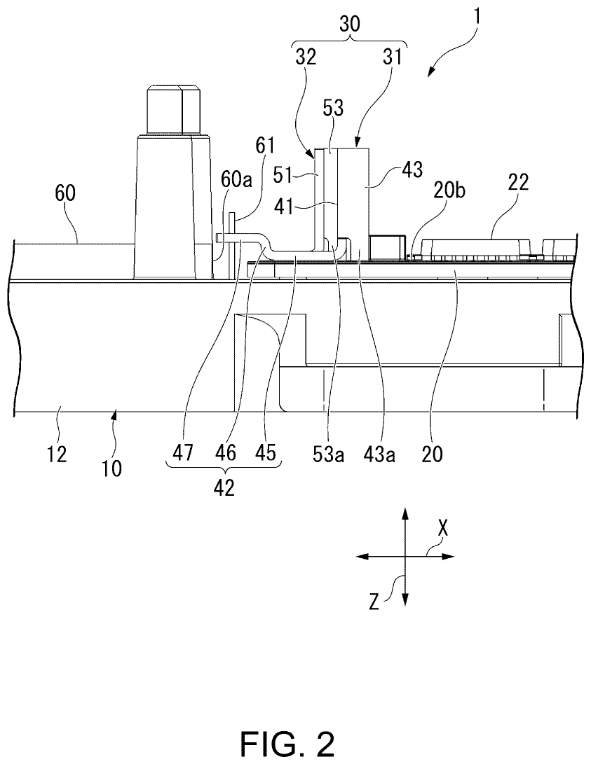

FIG. 1 is a perspective view showing a motor control device in an embodiment. FIG. 2 is a side view showing the motor control device of FIG. 1.

As shown in FIG. 1 and FIG. 2, the motor control device 1 is provided with, for example, an inverter function that converts DC power supplied from a battery (not shown) into AC power, and drives an AC motor (not shown) with the converted AC power. The motor control device 1 includes a case 10, a plate-shaped printed circuit board (substrate) 20 and a plurality of (for example, 8 in this embodiment) columnar electrolytic capacitors (capacitors) 60 housed in the case 10, and a busbar 30 surface-mounted (SMT) on a surface 20b of the printed circuit board 20.

The electrolytic capacitors 60 are arranged side by side in a direction perpendicular to the longitudinal direction (axial direction). Hereinafter, the longitudinal direction (axial direction) of the electrolytic capacitors 60 is referred to as the X direction. The direction in which the electrolytic capacitors 60 are arranged side by side is referred to as the Y direction. The direction (normal direction) perpendicular to the surface 20b of the printed circuit board 20 is referred to as the Z direction.

The printed circuit board 20 and the electrolytic capacitors 60 are arranged to be aligned in the extending direction of the printed circuit board 20 and the X direction. That is, the electrolytic capacitors 60 are arranged at one end portion 20a of the printed circuit board 20 in the X direction. Details of the electrolytic capacitors 60 will be described later.

### Case

The case 10 is formed in a box shape with one side open. The case 10, together with a cover (not shown) that closes the opening of this case 10, houses the printed circuit board 20, the busbar 30, and the plurality of electrolytic capacitors 60. The case 10 is provided with a plurality of fins 12 for heat dissipation on an outer surface 10a at the location where the printed circuit board 20 and the plurality of electrolytic capacitors 60 are housed. Hereinafter, the fins 12 for heat dissipation may be referred to as “heat dissipation fins 12.”

The plurality of heat dissipation fins 12 are, for example, arranged on the outer surface 10a of the case 10 at intervals in the Y direction. The plurality of heat dissipation fins 12 extend in the X direction from the side of the end portion 10b where the electrolytic capacitors 60 are housed to the side where the printed circuit board 20 is housed. The plurality of heat dissipation fins 12 protrude outward in the Z direction from the outer surface 10a of the case 10. The plurality of heat dissipation fins 12 dissipate heat of the printed circuit board 20, the busbar 30, and the plurality of electrolytic capacitors 60 to the outside of the case 10.

### Printed Circuit Board

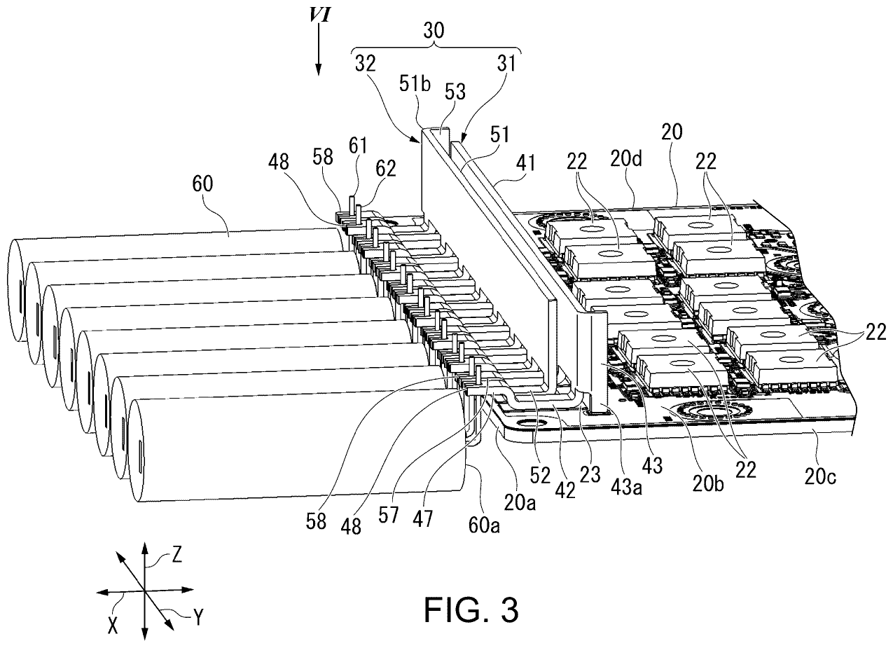

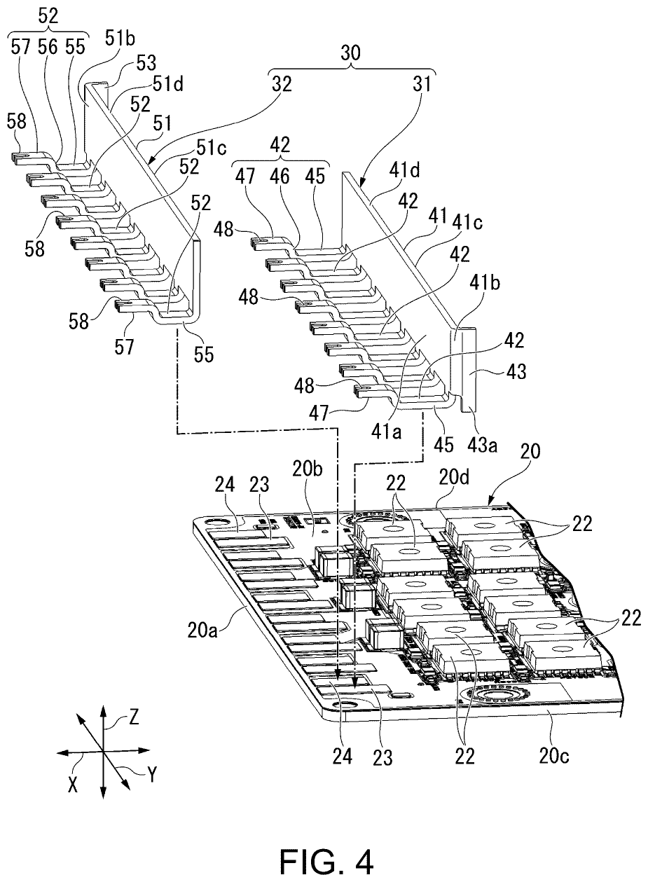

FIG. 3 is a perspective view of the motor control device of FIG. 1 with the case removed. FIG. 4 is an exploded perspective view of the motor control device of FIG. 3.

As shown in FIG. 3 and FIG. 4, the printed circuit board 20 is formed, for example, in a rectangular shape when viewed from the Z direction. The printed circuit board 20 is a PWB (Printed Wiring Board) on which a plurality of switching elements 22 are surface-mounted. The switching elements 22 have ON/OFF operations controlled by a switching control circuit (not shown), thereby operating the motor control device 1 under optimal conditions according to the driving state of the AC motor.

A plurality of first pattern terminals 23 and a plurality of second pattern terminals 24 are provided on the printed circuit board 20 at one end portion 20a on the side where the busbar 30 is arranged. The plurality of first pattern terminals 23 and the plurality of second pattern terminals 24 are arranged alternately at intervals in the Y direction. The plurality of first pattern terminals 23 and the plurality of second pattern terminals 24 are exposed on the surface 20b of the printed circuit board 20.

The first pattern terminals 23 are, for example, electrically connected to the positive electrodes of the switching elements 22 via wiring patterns (not shown) formed on the printed circuit board 20. The second pattern terminals 24 are, for example, electrically connected to the negative electrodes of the switching elements 22 via wiring patterns (not shown) formed on the printed circuit board 20.

In this embodiment, the first pattern terminals 23 are described as positive electrodes and the second pattern terminals 24 are described as negative electrodes, but the present invention is not limited thereto. As another example, the first pattern terminals 23 may be negative electrodes and the second pattern terminals 24 may be positive electrodes.

### Busbar

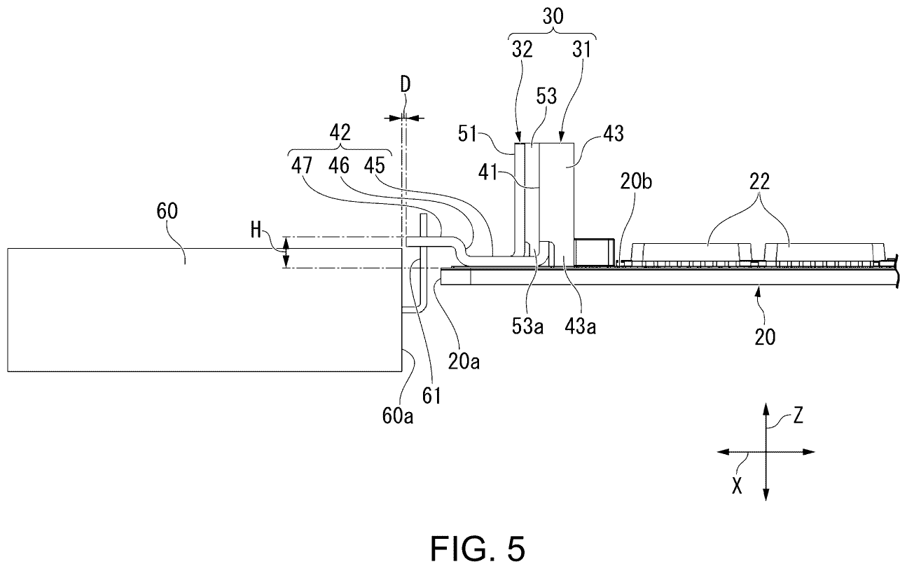

FIG. 5 is a view showing the connection state between the busbar 30 and the electrolytic capacitors 60, and corresponds to FIG. 2 described above.

As shown in FIG. 3 to FIG. 5, the busbar 30 is connected to the plurality of first pattern terminals 23 and the plurality of second pattern terminals 24 on the printed circuit board 20. The busbar 30 is surface-mounted on the surface 20b of the printed circuit board 20 through connection to the plurality of first pattern terminals 23 and the plurality of second pattern terminals 24. The busbar 30 electrically connects the plurality of electrolytic capacitors 60 and the plurality of switching elements 22.

The busbar 30 includes a first busbar 31 and a second busbar 32. In this embodiment, for example, the first busbar 31 is described as a positive electrode and the second busbar 32 is described as a negative electrode, but the present invention is not limited thereto. As another example, the first busbar 31 may be a negative electrode and the second busbar 32 may be a positive electrode.

The first busbar 31 is formed of a plate-shaped conductive material. The first busbar 31 has a first main body 41 extending in the Y direction along the plurality of first pattern terminals 23 and the plurality of second pattern terminals 24 on the printed circuit board 20, and a plurality of first busbar terminals 42 and a first leg portion 43 linked to the first main body 41. For example, there are 4 of each of the pattern terminals 23 and 24, totaling 8. There are also 8 first busbar terminals 42. The total number of these pattern terminals 23 and 24, and the number of the first busbar terminals 42 correspond to the number of the electrolytic capacitors 60.

The first main body 41 is formed in a plate shape that is long in the Y direction. That is, the first main body 41 is formed in a rectangular shape by extending at a constant height from one side edge 20c to the other side edge 20d of the printed circuit board 20 in the Y direction. The first main body 41 is arranged to be perpendicular to the surface 20b of the printed circuit board 20. That is, the thickness direction of the first main body 41 coincides with the X direction. Therefore, the first main body 41 is formed with as large an area as possible based on the width dimension in the Y direction and the height dimension in the Z direction.

In this embodiment, an example of arranging the first main body 41 perpendicular to the printed circuit board 20 is described, but the present invention is not limited thereto. As another example, the first main body 41 may intersect the printed circuit board 20. That is, it is sufficient for the first main body 41 to be arranged along the normal direction (Z direction) of the surface 20b of the printed circuit board 20.

The first main body 41 is arranged between one end portion 20a of the printed circuit board 20 and the plurality of switching elements 22. The first main body 41 is arranged close to the side of the plurality of switching elements 22, in the vicinity of the plurality of switching elements 22.

The plurality of first busbar terminals 42 are bent and extend from the edge 41a of the first main body 41 on the side of the printed circuit board 20 toward the side of the electrolytic capacitor 60. In other words, the plurality of first busbar terminals 42 are bent and extend from the edge 41a of the first main body 41 toward the side opposite to the switching elements 22. The plurality of first busbar terminals 42 are arranged at equal intervals in the Y direction.

The first busbar terminal 42 has a first pattern connection portion 45 that is bent and extends from the first main body 41, a first rising portion 46 that extends from the tip (the end opposite to the first main body 41) of the first pattern connection portion 45, and a first capacitor connection portion 47 that extends from the tip (the end opposite to the first pattern connection portion 45) of the first rising portion 46. The first pattern connection portion 45 extends along the first pattern terminal 23. The first pattern connection portion 45 is connected by solder to the first pattern terminal 23 of the printed circuit board 20 through surface mounting.

The first pattern connection portion 45 is electrically connected to the positive electrode of the switching element 22 via the first pattern terminal 23 and wiring pattern (not shown). That is, the first main body 41 is electrically connected to the positive electrode of the switching element 22 via the first pattern connection portion 45, the first pattern terminal 23, and wiring pattern.

The first rising portion 46 is bent and extends from the tip of the first pattern connection portion 45 to be separated from the printed circuit board 20 in the Z direction. In other words, the first rising portion 46 rises from the surface 20b of the printed circuit board 20.

The first capacitor connection portion 47 is bent and extends from the tip of the first rising portion 46 toward the side of the electrolytic capacitor 60 in parallel to the first pattern connection portion 45. That is, the first capacitor connection portion 47 is arranged at an interval from the printed circuit board 20 in the Z direction.

A recess 48 is formed at the tip of the first capacitor connection portion 47. The recess 48 is fitted to the first lead terminal 61 of the electrolytic capacitor 60, which will be described later.

The first leg portion 43 is bent and extends from the end portion 41b of the first main body 41 on the side of one side edge 20c of the printed circuit board 20 toward the side of the switching element 22. That is, the first leg portion 43 protrudes from the side surface 41c of the first main body 41 on the side of the switching element 22.

A protruding piece 43a that protrudes toward the printed circuit board 20 is integrally formed at the end portion of the first leg portion 43 on the side of the printed circuit board 20. The protruding piece 43a is connected to the surface 20b of the printed circuit board 20. In other words, the first leg portion 43 is in contact with the surface 20b of the printed circuit board 20.

The basic configuration of the second busbar 32 is similar to the configuration of the first busbar 31. Therefore, in the following description of each part of the second busbar 32, the description will be omitted by changing “first” to “second” in the names of each part of the first busbar 31 and changing the reference numerals. Only the points in the configuration of the second busbar 32 that differ from the first busbar 31 will be described.

The second busbar 32 is formed of a plate-shaped conductive material, and has a second main body 51, a plurality of second busbar terminals 52, and a second leg portion 53.

The second main body 51 is arranged between one end portion 20a of the printed circuit board 20 and the plurality of switching elements 22. The second main body 51 is arranged closer to the side of one end portion 20a of the printed circuit board 20 than the first main body 41. The second main body 51 is opposed to the first main body 41 in the X direction.

The plurality of second busbar terminals 52 each have a second pattern connection portion 55, a second rising portion 56, and a second capacitor connection portion 57. The second pattern connection portion 55 is connected by solder to the second pattern terminal 24 of the printed circuit board 20 through surface mounting. The second pattern connection portion 55 is electrically connected to the negative electrode of the switching element 22 via the second pattern terminal 24 and wiring pattern (not shown). That is, the second main body 51 is electrically connected to the negative electrode of the switching element 22 via the second pattern connection portion 55, the second pattern terminal 24, and wiring pattern.

The first busbar 31 and the second busbar 32 are arranged in a state where the first main body 41 and the second main body 51 are slightly offset in the Y direction. In this state, the plurality of second busbar terminals 52 are arranged between the plurality of first busbar terminals 42 in the Y direction. The detailed alignment state of these first busbar terminals 42 and second busbar terminals 52 will be described later.

A recess 58 is formed at the tip of the second capacitor connection portion 57. The recess 58 is fitted to the second lead terminal 62 of the electrolytic capacitor 60, which will be described later.

The second leg portion 53 is bent and extends from the side of the end portion 51b of the second main body 51 on the other side edge 20d of the printed circuit board 20 toward the side of the switching element 22. That is, the second leg portion 53 protrudes from the side surface 51c of the second main body 51 on the side of the switching element 22.

A protruding piece 53a of the second leg portion 53 is connected to the surface 20b of the printed circuit board 20. In other words, the second leg portion 53 is in contact with the surface 20b of the printed circuit board 20.

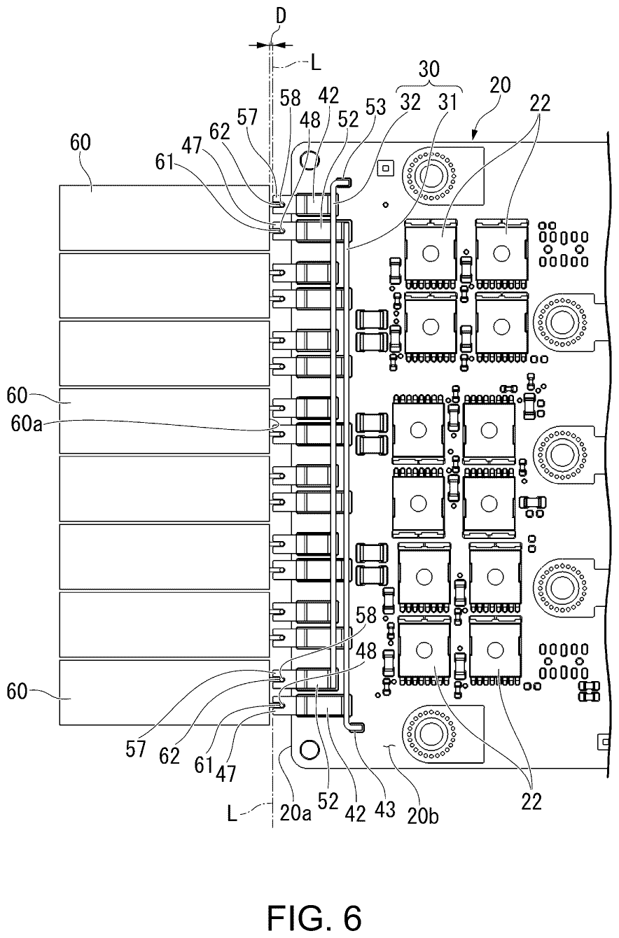

FIG. 6 is a plan view showing the electrolytic capacitor 60 and the area around from the arrow view of VI in FIG. 3.

As shown in FIG. 5 and FIG. 6, the first capacitor connection portions 47 of the first busbar terminals 42 and the second capacitor connection portions 57 of the second busbar terminals 52 are arranged side by side alternately to form a single row in the Y direction. In other words, the first capacitor connection portions 47 and the second capacitor connection portions 57 are linearly arranged along a straight line L extending in the Y direction. Specifically, the recesses 48 of the first capacitor connection portions 47 and the recesses 58 of the second capacitor connection portions 57 are linearly arranged along the straight line L extending in the Y direction. Additionally, the first capacitor connection portions 47 and the second capacitor connection portions 57 are positioned at the same height H in the direction away from the printed circuit board 20.

### Electrolytic Capacitor

The electrolytic capacitors 60 are arranged so that the end surfaces 60a on the side facing the busbar 30 are at the same distance D from the first capacitor connection portions 47 and the second capacitor connection portions 57.

As shown in FIG. 3, FIG. 5, and FIG. 6, the electrolytic capacitor 60 has a first lead terminal 61 protruding from the end surface 60a and a second lead terminal 62 protruding from the end surface 60a. The first lead terminal 61 and the second lead terminal 62 are spaced apart in the Y direction, and protrude from the end surface 60a of the electrolytic capacitor 60 toward the printed circuit board 20.

The first lead terminal 61 and the second lead terminal 62 protrude from the end surface 60a, and are bent and extend toward the opposite side of the case 10 (see FIG. 1) midway. The first lead terminal 61 and the second lead terminal 62 are arranged side by side alternately to form a single row in the Y direction. In other words, the first lead terminal 61 and the second lead terminal 62 are linearly arranged along the straight line L extending in the Y direction. The heights of the tips of the lead terminals 61 and 62 are the same.

Under such a configuration, the first capacitor connection portion 47 provided on the first busbar 31 and the second capacitor connection portion 57 provided on the second busbar 32 are arranged near the tips of the lead terminals 61 and 62. Thus, the first lead terminal 61 is inserted into the recess 48 of the first capacitor connection portion 47. In this state, the first lead terminal 61 is directly connected to the first capacitor connection portion 47 by solder. The second lead terminal 62 is inserted into the recess 58 of the second capacitor connection portion 57. In this state, the second lead terminal 62 is directly connected to the second capacitor connection portion 57 by solder.

Thus, the electrolytic capacitor 60 is electrically connected to the switching element 22 via the busbar 30. The electrolytic capacitor 60 has a function of suppressing fluctuations in DC voltage caused by the switching operation of the switching element 22.

In this embodiment, the capacitor is described using the electrolytic capacitor 60 as an example, but the capacitor is not limited to the electrolytic capacitor 60. As another example, a capacitor with a sufficiently large capacitance capable of suppressing fluctuations in DC voltage within a target value may also be adopted.

As described above, the motor control device 1 includes the printed circuit board 20 on which the switching elements 22 are surface-mounted, the busbar 30 that is surface-mounted on the printed circuit board 20 and connected to the switching elements 22, and the electrolytic capacitors 60 arranged alongside the printed circuit board 20 along the extending direction of the printed circuit board 20. The busbars 31 and 32 of the busbar 30 respectively include the main bodies 41 and 51, and the plurality of busbar terminals 42 and 52 linked to the main bodies 41 and 51. The busbar terminals 42 and 52 respectively have the pattern connection portions 45 and 55, the rising portions 46 and 56, and the capacitor connection portions 47 and 57. The rising portions 46 and 56 respectively rise from the surface 20b of the printed circuit board 20. The capacitor connection portions 47 are 57 are respectively bent and extend from the tips of the rising portions 46 and 56 toward the side of the electrolytic capacitor 60 in parallel to the pattern connection portions 45 and 55.

Since the busbar terminals 42 and 52 respectively have the rising portions 46 and 56 and the capacitor connection portions 47 and 57, the flexibility in layout of the electrolytic capacitors 60 in the normal direction of the printed circuit board 20 can be improved. Therefore, it is easy to achieve miniaturization of the motor control device 1 while securing the insulation distance between the printed circuit board 20 and the capacitor connection portions 47 and 57. For example, in the case where it is desired to increase the fin height of the heat dissipation fins 12 (see FIG. 1 and FIG. 2) formed along the electrolytic capacitors 60, it is possible to move the electrolytic capacitors 60 in the Z direction intersecting the printed circuit board 20, thereby securing a large fin height.

The first capacitor connection portions 47 of the first busbar terminals 42 and the second capacitor connection portions 57 of the second busbar terminals 52 are arranged side by side alternately to form a single row in the Y direction. In other words, the first capacitor connection portions 47 and the second capacitor connection portions 57 are linearly arranged along the straight line L extending in the Y direction. Specifically, the recesses 48 of the first capacitor connection portions 47 and the recesses 58 of the second capacitor connection portions 57 are linearly arranged along the straight line L extending in the Y direction. Particularly, the recesses 48 of the first capacitor connection portions 47 and the recesses 58 of the second capacitor connection portions 57 are linearly arranged along the straight line L. The recess 48 is fitted to the first lead terminal 61 of the electrolytic capacitor 60. The recess 58 is fitted to the second lead terminal 62 of the electrolytic capacitor 60. In this manner, the first lead terminals 61 and the second lead terminals 62 are linearly arranged along the straight line L.

Thus, the workability of soldering can be improved when connecting the capacitor connection portions 47 and 57 corresponding to the lead terminals 61 and 62 with solder. Therefore, the soldering operation can be facilitated. For example, the soldering operation can be performed by an automatic machine such as a robot, thereby improving productivity.

In addition, the first capacitor connection portions 47 and the second capacitor connection portions 57 are positioned at the same height H from the printed circuit board 20. Thus, the soldering operation can be performed even more suitably by an automatic machine such as a robot.

The end surfaces 60a of the electrolytic capacitors 60 are arranged at equal distances D from the first capacitor connection portions 47 of the first busbar terminals 42 and the second capacitor connection portions 57 of the second busbar terminals 52. This allows for uniformity in the charging and discharging distances of the electrolytic capacitors 60. Uniform utilization of the electrolytic capacitors 60 can be achieved.

The main bodies 41 and 51 of the busbars 31 and 32 are arranged to be opposed to each other in the X direction (the alignment direction of the switching elements 22 and the electrolytic capacitors 60). Therefore, the area required for mounting the busbars 31 and 32 on the printed circuit board 20 can be minimized, thereby achieving miniaturization of the motor control device 1. Since the current path between the busbar terminals 42 and 52 and the switching elements 22 can be shortened, the inductance can be reduced. Additionally, the switching elements 22 and the electrolytic capacitors 60 are connected via the busbar 30. The busbar 30 is arranged at one end portion 20a in the X direction of the printed circuit board 20 on which the switching elements 22 are surface-mounted. This makes it possible to secure the insulation distance between the switching elements 22 and the electrolytic capacitors 60.

The main bodies 41 and 51 of the busbars 31 and 32 are arranged to be opposed to each other in the X direction and are formed with as large an area as possible. Furthermore, the pattern connection portions 45 and 55 of the busbars 31 and 32 are respectively connected by soldering through surface mounting to the pattern terminals 23 and 24 that are surface-mounted on the surface 20b of the printed circuit board 20.

Therefore, the area required for surface-mounting the busbars 31 and 32 on the printed circuit board 20 can be minimized. The current path from the switching elements 22 to the busbars 31 and 32 (the first pattern connection portion 45, the second pattern connection portion 55) can be shortened.

Furthermore, the first pattern connection portion 45 and the second pattern connection portion 55, which are surface-mounted on the surface 20b of the printed circuit board 20, are connected to the electrolytic capacitors 60. Therefore, the current path from the switching elements 22 to the electrolytic capacitors 60 can be shortened.

By arranging the first main body 41 and the second main body 51, each with a large area, to oppose each other, and further shortening the current path, the inductance of the motor control device 1 can be reduced.

The first pattern connection portion 45 of the first busbar 31 and the second pattern connection portion 55 of the second busbar 32 are surface-mounted on the surface 20b of the printed circuit board 20. Furthermore, by connecting the first pattern connection portion 45 and the first pattern connection portion 45, which are surface-mounted on the surface 20b of the printed circuit board 20, to the electrolytic capacitor 60, the current path can be shortened. Thus, the miniaturization of the motor control device 1 can be achieved.

The first leg portion 43 protrudes from the side surface 41c of the first main body 41, and the second leg portion 53 protrudes from the side surface 51c of the second main body 51. These leg portions 43 and 53 are connected (in contact) to the surface 20b of the printed circuit board 20 via the protruding pieces 43a and 53a, respectively.

The main bodies 41 and 51 are arranged to be perpendicular to the surface 20b of the printed circuit board 20. Therefore, the posture of each of the main bodies 41 and 51 is unstable if considered individually. In such a posture, each of the leg portions 43 and 53 functions as a fall prevention mechanism for the main bodies 41 and 52. Thus, the reliability of the motor control device 1 can be improved.

### Modified Example

Next, a modified example of the motor control device 1 will be described based on FIG. 6.

FIG. 6 is a perspective view of the motor control device 1 in the modified example with the case 10 removed. FIG. 6 corresponds to FIG. 3 described above.

As shown in FIG. 6, a first tongue portion 44 may be integrally formed with the first main body 41 of the first busbar 31. A second tongue portion 54 may be integrally formed with the second main body 51 of the second busbar 32.

The first tongue portion 44 is arranged at the center in the Y direction of the edge 41d of the first main body 41 on the side opposite to the printed circuit board 20. The first tongue portion 44 is bent and extends from the edge 41d of the first main body 41 toward the side of the switching element 22. That is, the first tongue portion 44 extends in a direction perpendicular to the first main body 41. In other words, the first tongue portion 44 extends in a direction parallel to the surface 20b of the printed circuit board 20.

The second tongue portion 54 is arranged at the center in the Y direction of the edge 51d of the second main body 51 on the side opposite to the printed circuit board 20. The second tongue portion 54 is bent and extends from the edge 51d of the second main body 51 toward the side of the switching element 22. That is, the second tongue portion 54 extends in a direction perpendicular to the second main body 51. In other words, the second tongue portion 54 extends in a direction parallel to the surface 20b of the printed circuit board 20.

The second tongue portion 54 is arranged to overlap on top of the first tongue portion 44. Here, the first busbar 31 and the second busbar 32 are arranged in a state where the first main body 41 and the second main body 51 are slightly offset in the Y direction. Therefore, when viewed from the Z direction, a portion of the first tongue portion 44 is exposed from the second tongue portion 54.

Under such a configuration, when placing the busbars 31 and 32 on the printed circuit board 20 at the time of assembling the motor control device 1, an industrial robot (not shown) or the like transports the busbars 31 and 32 by suction-holding the respective tongue portions 44 and 54. In the case of suction-holding, the upper surfaces 44a and 54a of the tongue portions 44 and 54, which are surfaces on the side opposite to the printed circuit board 20, are suction-held.

Here, each of the tongue portions 44 and 54 is formed by bending 90° with respect to the corresponding main bodies 41 and 52. Therefore, when the tongue portions 44 and 54 are suction-held and transported onto the printed circuit board 20, the main bodies 41 and 51 are transported while maintaining a posture perpendicular to the surface 20b of the printed circuit board 20. In that posture, the protruding pieces 43a and 53a of the leg portions 43 and 53 are inserted into the printed circuit board 20 to be connected. This completes the assembly of the busbars 31 and 32 to the printed circuit board 20.

Thus, according to the modified example described above, the assembly workability of the motor control device 1 can be improved.

The present invention is not limited to the aforementioned embodiments, and includes various modifications made to the aforementioned embodiments within a scope that does not deviate from the spirit of the present invention.

For example, in the above embodiment, the number of the electrolytic capacitors 60 is 8, and the total number of the pattern terminals 23 and 24, and the number of the busbar terminals 42 and 52 correspond to the number of the electrolytic capacitors 60. However, the present invention is not limited thereto, and the number of the electrolytic capacitors 60 can be any arbitrary number. The total number of the pattern terminals 23 and 24, and the number of the busbar terminals 42 and 52 may be determined correspondingly.

In the above embodiment, the first leg portion 43 is bent and extends from the end portion 41b of the first main body 41 on the side of one side edge 20c of the printed circuit board 20 toward the side of the switching element 22. The second leg portion 53 is bent and extends from the side of the end portion 51b of the second main body 51 on the other side edge 20d of the printed circuit board 20 toward the side of the switching element 22. The protruding pieces 43a and 53a of the leg portions 43 and 53 are connected to the surface 20b of the printed circuit board 20. However, the present invention is not limited thereto, and the leg portions 43 and 53 may protrude from the side surfaces of the main bodies 41 and 51 to be in contact with the surface 20b of the printed circuit board 20. By configuring in this manner, the leg portions 43 and 53 can function to prevent the busbars 31 and 32 from falling.

In the above modified example, the first tongue portion 44 is bent and extends from the center in the Y direction of the edge 41d of the first main body 41 toward the side of the switching element 22, and the second tongue portion 54 is bent and extends from the center in the Y direction of the edge 51d of the second main body 51 toward the side of the switching element 22. However, the present invention is not limited thereto, and the tongue portions 44 and 54 may respectively extend from the edges 41d and 51d of the main bodies 41 and 51. They are not necessarily bent and extend from the main bodies 41 and 51. It is sufficient if the tongue portions 44 and 54 can be grasped or suction-held by an industrial robot (not shown) to be transported.

Furthermore, it is possible to appropriately replace the components in the aforementioned embodiments with known components within the scope of the present invention, and the aforementioned modified examples may be combined as appropriate.

### REFERENCE SIGNS LIST

1 . . . motor control device, 10 . . . case, 10a . . . outer surface, 10b . . . end portion, 12 . . . heat dissipation fin (fin), 20 . . . printed circuit board (substrate), 20a . . . one end portion, 20b . . . surface, 20c . . . side edge, 20d . . . side edge, 22 . . . switching element (heating element), 23 . . . first pattern terminal, 24 . . . second pattern terminal, 30 . . . busbar, 31 . . . first busbar, 32 . . . second busbar, 41 . . . first main body (main body), 41a . . . edge, 41b . . . end portion, 41c . . . side surface, 41d . . . edge, 42 . . . first busbar terminal (busbar terminal), 43 . . . first leg portion, 43a . . . protruding piece, 44 . . . first tongue portion, 44a . . . upper surface, 45 . . . first pattern connection portion, 46 . . . first rising portion (rising portion), 47 . . . first capacitor connection portion (connection portion), 48 . . . recess, 51 . . . second main body (main body), 51b . . . end portion, 51c . . . side surface, 51d . . . edge, 52 . . . second busbar terminal (busbar terminal), 53 . . . second leg portion, 53a . . . protruding piece, 54 . . . second tongue portion, 54a . . . upper surface, 55 . . . second pattern connection portion, 56 . . . second rising portion (rising portion), 57 . . . second capacitor connection portion (connection portion), 58 . . . recess, 60 . . . electrolytic capacitor (capacitor), 60a . . . end surface, 61 . . . first lead terminal (lead terminal), 62 . . . second lead terminal (lead terminal), D . . . distance, H . . . height, L . . . straight line

1. A motor control device, comprising:
a substrate on which a heating element is surface-mounted;
a busbar that is surface-mounted on the substrate and is connected to the heating element; and
a capacitor that is arranged alongside the substrate along an extending direction of the substrate and is electrically connected to the heating element via the busbar,
wherein the busbar has:
a main body that is connected to the substrate; and
a busbar terminal that is linked to the main body and is connected to the capacitor, and
the busbar terminal has:
a rising portion that rises from a surface of the substrate; and
a connection portion that is bent and extends from an end portion of the rising portion on a side opposite to the substrate toward the capacitor, and is connected to the capacitor.

2. The motor control device according to claim 1, comprising a plurality of the capacitors,
wherein each of the capacitors has a lead terminal connected to the connection portion respectively, and each of the lead terminals is arranged to align in one direction,
the busbar has a plurality of the busbar terminals connected to the plurality of the capacitors, and
each of the connection portions is arranged to align in the same direction as an alignment direction of the lead terminals.

3. The motor control device according to claim 1, wherein the busbar comprises a first busbar and a second busbar, connected to each one of the capacitors respectively,
the main body comprises a first main body provided on the first busbar, and a second main body provided on the second busbar, and
the first main body and the second main body are arranged to be opposed to each other in an alignment direction of the heating element and the capacitor, between the heating element and the capacitor.

4. The motor control device according to claim 1, wherein the main body comprises a tongue portion extending from an end portion of the main body on a side opposite to the substrate.

5. The motor control device according to claim 4, wherein the tongue portion extends in a direction parallel to the substrate.

6. The motor control device according to claim 1, wherein the main body comprises a leg portion protruding from a side surface of the main body and being in contact with the substrate.

7. The motor control device according to claim 6, wherein the leg portion is connected to the substrate.

8. The motor control device according to claim 2, wherein the busbar comprises a first busbar and a second busbar, connected to each one of the capacitors respectively,
the main body comprises a first main body provided on the first busbar, and a second main body provided on the second busbar, and
the first main body and the second main body are arranged to be opposed to each other in an alignment direction of the heating element and the capacitor, between the heating element and the capacitor.
